(19) United States
(12) Patent Application Publication
(10) Pub. No.: US 2004/0052146 A1
(43) Pub. Date: Mar. 18, 2004

(54) Memory device having bitline equalizing voltage generator with charge reuse

(76) Inventor: Jae-Yoon Sim, Suwon-shi (KR)

Correspondence Address: HARNESS, DICKEY & PIERCE, P.L.C., P.O. BOX 8910, RESTON, VA, 20195, US

(21) Appl. No.: 10/635,434

(22) Filed: Aug. 7, 2003

(30) Foreign Application Priority Data
Sep. 18, 2002 (KR) 2002-57031

(51) Int. Cl. G11C 8/00

(52) U.S. Cl. 365/230.03

(57) ABSTRACT

A semiconductor memory device includes a bitline equalizing voltage generator for using boost voltage. The semiconductor memory device includes a sense amplifier shared by a first memory block and a second memory block, bitline isolation circuits, bitline equalizing circuits, a bitline equalizing voltage circuit, and bitline equalizing signal generator. The bitline isolation selectively connects the first or second memory block with the sense amplifier in response to the first or second bitline isolation signals. The bitline equalizing circuits precharge the bitlines of the first and second memory blocks with bitline precharge voltage in response to the first and second bitline equalizing signals. The bitline equalizing voltage generator provides bitline equalizing voltage by reusing the boost voltage on the bitline isolation signal and thereby connects with bitline equalizing signal. Accordingly, since the voltage, which is discharging from the bitline isolation signal, is reused with the voltage to increase the bitline equalizing signal level, it is proper to use in the low power operation mode of the memory device. Likewise, during the low power operation, if external voltage comes to be low, the bitline equalizing signal rises as much as a certain level higher than the external voltage so that the bitlines can be precharged reliably.

### FIELD OF THE INVENTION

This invention relates to semiconductor memory devices and more particularly to a bitline equalizing voltage generator recycling precharged voltage. This application claims priority from Korean Patent Application No. 2002-0057031, filed on Sep. 18, 2002, the contents of which are herein incorporated by reference in their entirety

### BACKGROUND OF THE INVENTION

Among semiconductor memory devices, dynamic random access memories (DRAMs) sense and amplify data stored in memory cells by means of a sense amplifier.

The sense amplifier, which is coupled to a bitline, compares a potential difference between a bitline precharge voltage and a bitline voltage level developed by charge-sharing between the bitline and a capacitor of a selected memory cell and then finds data stored in the selected memory cell. It is also alterable to design such that the sense amplifier is shared by adjacent memory blocks and detects a memory cell of one memory block or another memory block by selection, as well as being assigned exclusively to one memory block.

FIG. 1 shows an example of a memory device constructed of the shared sense amplifier architecture. Referring to FIG. 1, there are several core circuits, such as bitline equalizing circuits 112 and 122, bitline isolation circuits 116,126, and a column selection circuit 140, arranged between a shared sense amplifier 130 and two adjacent memory blocks 110 and 120,.

Each of the bitline equalizing circuits 112 and 122 provides a precharge voltage VBL to bitline pairs BL/BLB in first and second memory blocks 110 and 120 before the sense amplifier 130 develops a potential difference of the bitlines. The first bitline isolation circuit 116 turns on and thereby electrically connects the bitline pair BL/BLB of the first memory block 110 with the sense amplifier 130, when the data of the memory cell in the first memory block 110 is sensed, while the second bitline isolation circuit 126 turns off and thereby electrically disconnects the sense amplifier 130 with the bitline pair BL/BLB of the second memory block 120.

On the contrary, when the bitline pair BL/BLB of the second memory block 120 and the sense amplifier 130 are connected via the second bitline isolation circuit 126, the bitline pair BL/BLB of the first memory block 110 and the sense amplifier 130 are electrically disconnected via the first bitline isolation circuit 116. The column selection circuit 140 transfers the data of the first and second memory blocks 110 and 120, which are amplified by the sense amplifier 130, to data input/output lines 10 and 10B.

In the shared sense amplifier structure, the sensing procedure of the memory cell MC1 of the second memory block 120 after sensing data of the memory cell MC0 of the first memory block 110 is as follows.

When first and second bitline equalizing signals PEQi and PEQj are high levels of an external voltage VEXT, the bitlines BL and BLB are pre-charged with the bitline precharge voltage VBL.

Afterwards, in order to sense the memory cell MC0 of the first memory block 110, the first bitline equalizing signal PEQi is set to a low level of a ground voltage (or a substrate voltage) VSS and the first bitline isolation circuit PISOi is set to a high level of a boosting voltage VPP. A word line WLn−1 of the memory cell MC0 is also set to the boosting voltage VPP. As a result of that, the data of the memory cell MC0 transfers to the sense amplifier 130 by way of charge-sharing with the bitline BL.

On the other side, for sensing the memory cell MC1 of the second memory block 120, when the second bitline equalizing signal PEQj becomes a low level of VSS, a wordline WL1 is driven with a boosting voltage VPP and the second bitline isolation signal PISOj becomes a high level of VPP. Then, the data of the memory cell MC1 is transferred to the sense amplifier 130 by way of the charge-sharing action with the bitline BL. In the meantime, the first bitline equalizing signal PEQi becomes a high level of VEXT, so that the bitlines BL and BLB of the first memory block 110 are precharged to the bitline precharge voltage VBL.

Such operation, hereinafter, will be explained with reference to FIG. 2. By changing the first bitline equalizing signal PEQi from the low VSS to the high VEXT, the bitlines BL/BLB are pre-charged with the bitline pre-charge coltage VBL. The speed of pre-charging the bitlines BL/BLB with the bitline pre-charge voltage VBL is dependent on the gate-source voltages VGS of first and second equalizing transistors 113 and 114.

In harmonizing the DRAM device with a low voltage environment, the gate-source voltages Vgs of the first and second equalizing transistors 113 and 114 are settled about at 0.5V when the internal voltage VINT is lowered to 1.0V in accordance with the external voltage VEXT that downs to 1.0V and the bitline precharge voltage VBL is established on 0.5V a half of the internal voltage VINT. If threshold voltages of the first and second equalizing transistors 113 and 114 are higher than 0.5V, the bitlines BL/BLB are not pre-charged thereby because the transistors 113 and 114 are not turned on. Therefore, it needs to charge the bitline equalizing signals PEQi and PEQj, which are applied to the gates of the first and second transistors 113 and 114, up to a voltage level higher than the external voltage VEXT.

In contrast, when the DRAM is stationed in a standby mode under the low-voltage operating condition, the bitlines BL and BLB coupled to the sense amplifier 130 are pre-charged with the bitline pre-charge voltage VBL through the first and second bitline isolation circuits 116 and 126 respectively. During this, the first and second equalizing signals PEQi and PEQj must have voltage levels higher than the bitline pre-charge voltage VBL by the threshold voltages of the equalizing transistors 113 and 114. Namely, the equalizing signals PEGi and PEGj are normally operative ar least when their voltage levels are as much as VINT+Vth=VEXT+Vth.

Therefore, it is required under the low-voltage operating condition for the bitline equalizing signals PEQi and PEQj to be bootstrapped up to their required voltage levels, higher than the external voltage, by means of a pumping operation. However, such a voltage pumping inevitably causes current consumption even though the DRAM is designed to be operable in the low-voltage operational environment.

### SUMMARY OF THE INVENTION

It is therefore an object of present invention to provide a semiconductor memory device capable of equalizing bitline pairs with smaller current consumption in the condition of a low-voltage environment. It is also an object of the present invention to provide a semiconductor memory device capable of equalizing bitline pairs without

without an internal pumping operation in the condition of a low-voltage environment.

One embodiment of this invention provides that semiconductor devices include a shared sense amplifier between a first memory block and a second memory block, bitline isolation circuits, bitline equalizing circuits, a bitline equalizing voltage generator, and bitline signal generators. The shared sense amplifier is selectively connected through each of the bitline isolation circuits to the first and second memory blocks in response to the first and second bitline isolation signals, respectively. The bitlines on the first and second memory blocks are precharged with precharge voltage by the bitline equalizing circuits in response to the first and second bitline equalizing signals.

The bitline equalizing voltage generator generates bitline equalizing voltage by recycling boosting voltage on the bitline isolation signal, and then provides it to a bitline equalizing signal. The bitline equalizing signal generator generates a first and second bitline equalizing signals, which are bitline equalizing voltage or external voltage, in response to the first and second memory block select signal.

More specifically, the bitline equalizing voltage generator includes a first controller which receives boosting voltage and generates a first control signal in response to the first and second memory select block signals, a second controller which receives external voltage and generates a second control signal in response to the first control signal, an equalizer which equalizes a first and second bitline isolation signals in response to the first control signal, a driver provides the first and second bitline isolation signal with external voltage in response to the second control signal, and a transfer circuit which provides bitline equalizing voltage having a half level of the boosting voltage when the first or second bitline isolation signal is inactivated.

The bitline equalizing signal generators include a first driver which receives the first or the second memory block selection signal and then generates the first or the second bitline equalizing signal each holding bitline equalizing voltage, and a second driver which receives a first or a second complement memory block select signal and then generates the first or second bitline equalizing signals each holding external voltage.

Another embodiment according to the present invention provides the semiconductor device includes a bitline equalizing voltage generator for generating bitline equalizing voltage, which is coupled to the bitline equalizing signal, by recycling boosting voltage on a word line drive signal. The bitline equalizing voltage generator includes a word line drive signal generator for generating a word line drive signal with boosted voltage level by receiving a word line address signal which is generated from a row decoder and a bitline equalizing voltage driver for transferring a word line drive signal wit a boosted voltage level as a bitline equalizing voltage in response to the word line drive pulse signal which is generated at a transition time both bitline pre-charge voltage and address signal.

The bitline equalizing voltage driver includes a first P-MOS transistor receiving word line drive pulse signal to its gate and receiving word line driver signal to its source, and a second P-MOS transistor including its source connected to the drain of the first P-MOS transistor and its drain receiving the bitline equalizing voltage.

Another object of this present invention is that memory devices include a bitline equalizing voltage generator, an external voltage detector, a bitline equalizing voltage detector, an oscillator, a charge pump circuit, and a switch circuit. The bitline equalizing voltage generator generates bitline equalizing voltage coupled to bitline equalizing signal by recycling boost voltage on the bitline isolation signal.

The external voltage detector generates a first enable signal by comparing the external voltage with a reference voltage. The bitline equalizing voltage detector generates a second enable signal by comparing the bitline equalizing voltage with bitline pre-charge voltage. The oscillator generates an oscillation signal in response to the first and second enable signal, and the charge pump circuit raises the external voltage to bitline equalizing voltage in response to the oscillation signal. The switch circuit provides the external voltage to bitline equalizing voltage in response to the first enable signal.

Preferably, the external voltage detector includes a voltage divider, a comparator, and a driver. The voltage divider has a first to a third resistor which are serially connected each other between external voltage and ground voltage, wherein both terminals of the first resistor are connected to a transistor in which its gate receives a first enable signal. The comparator compares reference voltage with the node level of between a second resistor and a third resistor, and therefore the driver generates a first enable signal fed from the output of the comparator. The bitline equalizing voltage detector includes a voltage down converter, a comparator, and a driver. The voltage down converter includes a diode connected NMOS transistor and a resistor, which are serially connected between bitline equalizing voltage and ground voltage.

The comparator compares the bitline precharge voltage with the node level of between NMOS transistor of the voltage down converter and the resistor, and the driver generates a second enable signal fed from the output of the comparator. Accordingly, the memory device according to the present invention is proper for the low voltage operation mode because a charge pumping operation for increasing the bitline equalizing signal level is less needed based on the recycling of the boost voltage, which is on the level of bitline isolation signal or word line enable signal, as bitline equalizing voltage during a discharging period.

Moreover, if, during the low power operation, the external voltage on the memory device becomes lower, it is more stable for precharging the bitlines because it is possible to raise the bitline equalizing signal level more than a certain voltage.

### BRIEF DESCRIPTION OF THE DRAWINGS

The forgoing and other objects, features and advantages of the invention will be apparent from the more particular description of a preferred embodiment with reference to the accompanying, of which:

FIG. 1 is a circuit diagram showing a typical structure of shared sense amplifiers;

FIG. 2 shows voltage waveforms of a wordline, isolation signals, and equalizing signals, timely operable with the circuit shown in FIG. 1;

FIGS. 3A and 3B are circuit diagrams showing bitline isolation signal generators;

FIG. 4 is a circuit diagram showing a bitline equalizing voltage generator according to a first embodiment of the present invention;

FIGS. 5A and 5B are circuit diagrams showing bitline equalizing signal generators;

FIG. 6 is a circuit diagram showing a bitline equalizing voltage generator according to a second embodiment;

FIG. 7 is a circuit diagram showing a sub-wordline driver;

FIG. 8 illustrates voltage waveforms of a wordline, isolation signals, and equalizing signals, timely operating in the circuit of FIG. 1, accompanying with the bitline equalizing voltage generator shown in FIG. 6;

FIG. 9 is circuit diagram showing a bitline equalizing voltage generator according to a third embodiment;

FIG. 10 is a circuit diagram showing an external voltage detector of the FIG. 9;

FIG. 11 is a circuit diagram showing an equalizing voltage detector of FIG. 9;

FIG. 12 is a circuit diagram showing an oscillator of FIG. 9;

FIG. 13 is a graphic diagram characterizing an operation of the bitline equalizing voltage generator shown in FIG. 9.

### DETAILED DESCRIPTION OF THE INVENTION

The present invention will be described more fully hereinafter with reference to the accompanying drawings.

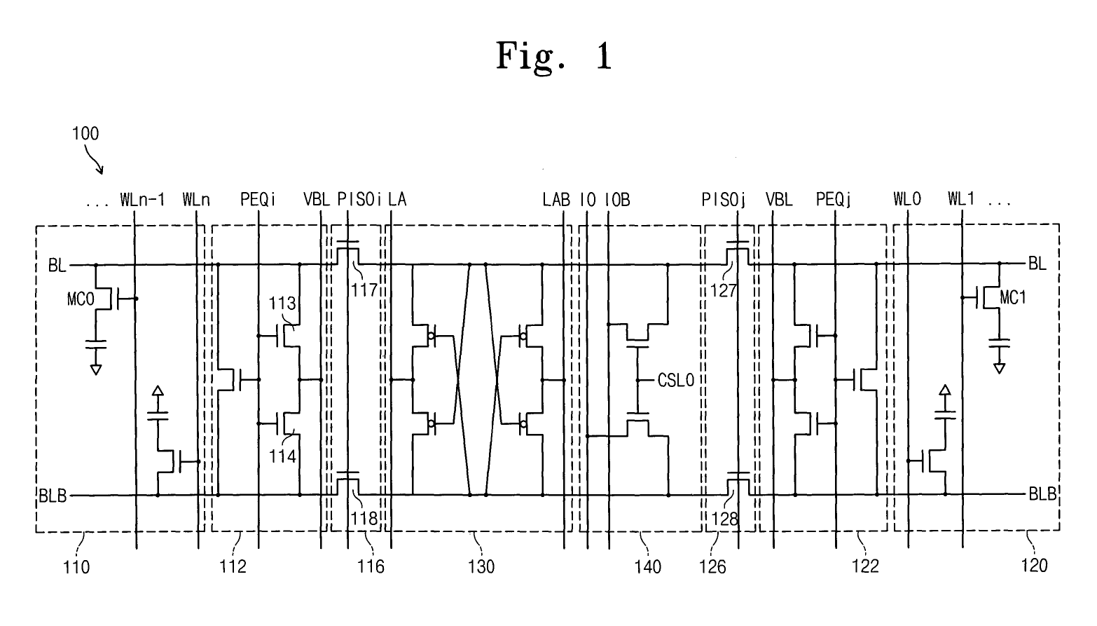

The present invention is applicable to a semiconductor memory device having shared-type sense amplifiers each of which is operatively coupled to a plurality of blocks, in which as shown in FIG. 1 the shared sense amplifier 130 is selectively connected to an alternative one of the first and second memory blocks, 110 and 120. Also assuming in the embodiments of the present invention is that the bitline equalizing signals, PEQi and PEQj, are driven with the external voltage VEXT and the bitline isolation signals, PIOi and PISOj, with the boost voltage VPP higher than the external voltage VEXT.

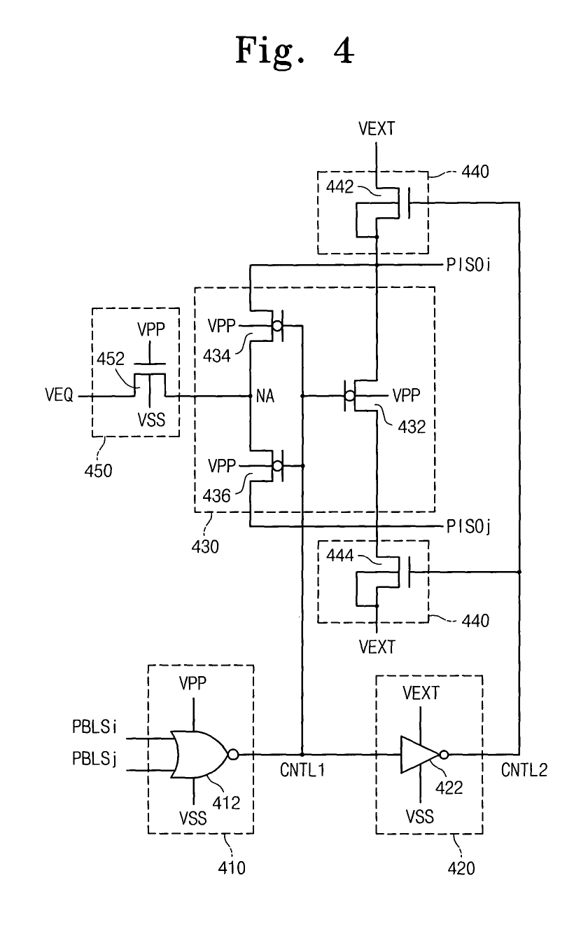

FIGS. 3A and 3B illustrate circuits of the bitline isolation signal generators, respectively for PISOi and PISOj. Referring to FIG. 3A, a first bitline isolation signal generator uses the boost voltage VPP as a power source and generates the first bitline isolation signal PISOi in response to both a first block selection signal PBLSiB (the complementary signal of PBLSi) and a second memory block selection signal PBLSj. Referring to FIG. 3B, a second bitline isolation signal generator also uses the boost voltage VPP as a power source and generates the second bitline isolation signal PISOj in response to both the second complement block select signal PBLSjB (the complementary of PBLSj) and the first memory block selection signal PBLSi.

The first and second bitline isolation signals, PISOi and PISOj, are activated in an alternative consition each other. When selecting the first memory block 110, the first memory block selection signal PBLSi is active with a high level and thereby the first bitline isolation signal PISOi is set to a high level of VPP, while the second bitline isolation signal PISOj is held on a low level of VSS. To the contrary, when selecting the second memory block 120, the second memory block selection signal PBLSj is active with a high level to set the second bitline isolation signal PISOj on a high level of VPP, while the first bitline isolation signal PISOi is held on a low level of VSS.

FIG. 4 illustrates a circuit of the bitline equalizing voltage generator according to the first embodiment of the present invention. The bitline equalizing voltage generator 400 transfers the boot voltage VPP to the bitline equalizing voltage VEQ when either the first bitline isolation signal PISOi or the second bitline isolation signal PISOj changes from a high level of VPP to a low level of VSS. The bitline equalizing voltage generator includes a first controller 410, a second controller 420, an equalizer 430, a driver 440, and a transfer circuit 450.

The first controller 410 is driven by the boost level VPP and has an OR logic gate generating a first control signal CNTL1 in response to the first and second memory block select signals PBLSi and PBLSj.

The second controller 420 is driven by the external voltage level VEXT and has an inverter 422 generating a second control signal CNTL2 in response to the first control signal CNTL1. The equalizer 430 has transistors 432,434, and 436 for equalizing the first and second bitline isolation signals, PSIOi and PISOj, in response to the first control signal CNTL1.

The controller 440 has transistors 442 and 444 respectively activating the first and second bitline isolation signals PSIOi and PISOj which are driven by the external voltage VEXT.

The transfer circuit 450 is constructed of an NMOS transistor 452 whose gate is coupled to the boost voltage VPP, so that a voltage level at a node NA of the equalizer 430 is charged to the equalizing voltage VEQ.

The operation of the bitline equalizing voltage generator 400 proceeds as follows.

First, when the first and second block select signals PBLSi and PBLSj are low levels, the first control signal CNTL1 is set to a low level and then the second control signal CNTL2 is set to a high level.

Responding to the second control signal CNTL2 of a high level, two transistors 442 and 444 of the driver 440 are turned on and thereby the first and second bitline isolation signals PISOi and PISOj are charged up to the external voltage VEXT. And responding to the first control signal CNTL1 of a low level, three transistors 432, 434, and 436 are turned on and thereby the first and second isolation signals PISOi and PISOj go to the same level with the external voltage VEXT.

Second, when the first memory block 110 is selected, the first control signal CNTL1 is set to a high level while the second control signal CNTL2 to a low level. Accordingly, the first bitline isolation signal PISOi becomes the boost voltage level of VPP by the first bitline isolation signal generator shown in FIG. 3A, and the second bitline isolation signal PISOj becomes the ground voltage level by the second bitline isolation signal generator shown in FIG. 3B. Namely, according to the first control signal CNTL1 of high level, three PMOS transistors of the equalizer 430, 432, 434, and 436, are all turned off while two NMOS transistors of the driver 440, 442 and 444, are all turned off in response to the second control signal CNTL 2 of a low level.

At that time, as the NMOS transistors 117 and 118 of the bitline isolation circuit 116 shown in FIG. 1 are turned on in response to the first bitline isolation signal PISOi of the boost voltage VPP, a data bit stored in the memory cell MC0 is detected by the sense amplifier 130.

Third, when the first memory block 110 is non-selected, the first and second control signals CNTL1 and CNTL2 are set to a low level of VSS and a high level of VEXT, respectively, in response to the first and second memory block signals, PBLSi and PBLSj, of low levels.

At this time, the first bitline isolation signal PISOi holds the boost voltage level VPP while the second bitline isolation signal PISOj holds the ground voltage level VSS. As the second control signal CNTL2 of the external voltage level VEXT is applied to the driver 440, the first and second NMOS transistors, 442 and 444, which are configured with diode-connection, are turned off and on respectively.

Also, the three transistors, 432, 434, and 436, of the equalizer 430 are all turned on in response to the first control signal CNTL1 of the ground voltage level VSS, so that the voltage level of the node NA is developed to an intermediate level between the boost voltage VPP of the first bitline isolation signal PISOi and the ground level VSS of the second bitline isolation signal PISOj. The voltage level of the node NA of VPP/2 is transferred to the equalizing voltage VEQ through the transfer circuit 450.

It means that the equalizing voltage VEQ is established by using charges supplied from the boost voltage VPP while the first bitline isolation signal PISOi goes to the ground voltage level VSS from the boost voltage VPP by means of the first bitline isolation signal generator of FIG. 3A.

Fourth, when the second memory block 120 is selected, both the equalizer 430 and the driver 440 of the bitline equalizing voltage generator 400 are all turned off as is the same with the case of selecting the first memory block 110.

As the second bitline isolation signal PISOj shown in FIG. 3B is goes to a high level of VPP, the second memory block 120 is electrically connected with the sense amplifier 130 while the first memory block 110 is electrically isolated from the sense amplifier 130 because the first bitline isolation signal PISOi shown in FIG. 3A maintains a low level.

Five, when the second memory block 120 of FIG. 1 is not selected, as the same with the case of non-selecting the first memory block 110, the bitline equalizing voltage VEQ is set to the intermediate voltage level VPP/2 between the ground voltage of the first bitline isolation signal PISOi and the boost voltage VPP of the second bitline isolation signal PISOj.

It also means that the equalizing voltage VEQ is established by using charges supplied from the boost voltage VPP while the second bitline isolation signal PISOj goes to the ground voltage level VSS from the boost voltage VPP by means of the second bitline isolation signal generator of FIG. 3B.

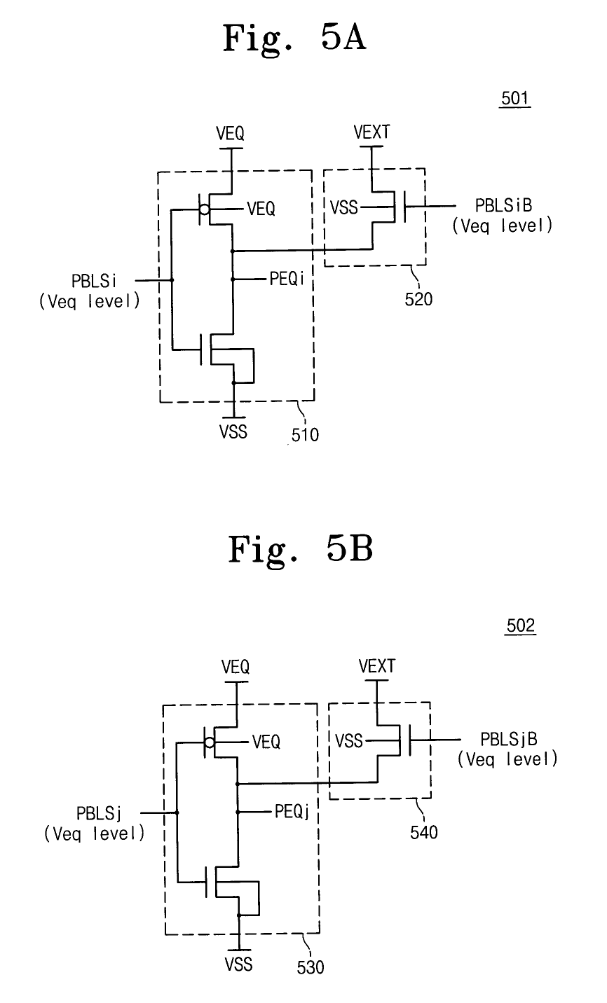

FIGS. 5A and 5B shows circuits of the bitline equalizing signal generators. The first bitline equalizing signal generator of FIG. 5A includes a first driver 510 for providing the first bitline equalizing signal PEQi charged with the bitline equalizing voltage level VEQ in response to the first memory block selection signal PBLSi and a second driver 520 for providing the first bitline equalizing signal PEQi charged with the external voltage level VEXT in response to the first complement block selection signal PBLSiB.

The first driver 510 is connected between the bitline equalizing voltage VEQ and the ground voltage VSS and constituted of an inverter to generate the first bitline equalizing signal PEQi in response to the first memory block selection signal PBLSi.

The second driver 520 is connected between the external voltage VEXT and the ground voltage VSS and formed of an NMOS transistor whose gate is coupled to the first complement block selection signal PBLSiB.

The operation of the first bitline equalizing signal generator of FIG. 5A is as follows.

When the first memory block selection signal PBLSi is a high level, the fist bitline equalizing signal PEQi becomes a low level of VSS and thereby the bitlines BL/BLB of the first memory block 110 is inhibited from being precharged. Then, the sensing operation for the selected memory cell starts with the connection between the bitline of first memory block 110 and the sense amplifier circuit 130.

On the contrary, when the first memory block selection signal PBLSi is a low level as the first memory block 110 is not selected, the first bit equalizing signal PEQi is driven by the first driver 510 with the bitline equalizing voltage VEQ or by the second driver 520 with the external voltage VEXT. During this, the first bitline equalizing signal PEQi is required to rise up to a high level in order to pre-charge the bitlines BL/BLB of the first memory block 110.

It is possible to raise the first bitline equalizing signal PEQi rapidly by reusing the charges supplied from the boost voltage VPP of the first bitline isolation signal PISOi in the bitline equalizing voltage generator 400 of FIG. 4.

Moreover, even though the external voltage VEXT is not enough to be a high level normally, the bitlines BL/BLB of the first memory block 110 of FIG. 1 can be easily pre-charged therein because the first bitline equalizing signal PEQi with the bitline equalizing voltage VEQ, which is higher than the external voltage VEX, has a sufficient voltage level to make the NMOS transistors 113 and 114 of the bitline equalizing circuit 112 be conductive.

FIG. 5B shows the second bitline equalizing signal generator, its structure and operation being similar to those of the first bitline equalizing signal generator shown in FIG. 5A.

Briefly, if the second memory block 120 is selected, the second bitline equalizing signal PEQj becomes a low level of VSS. If the second memory block 120 is not selected, the second bitline equalizing signal PEQj is driven by the bitline equalizing voltage VEQ or the external voltage VEXT.

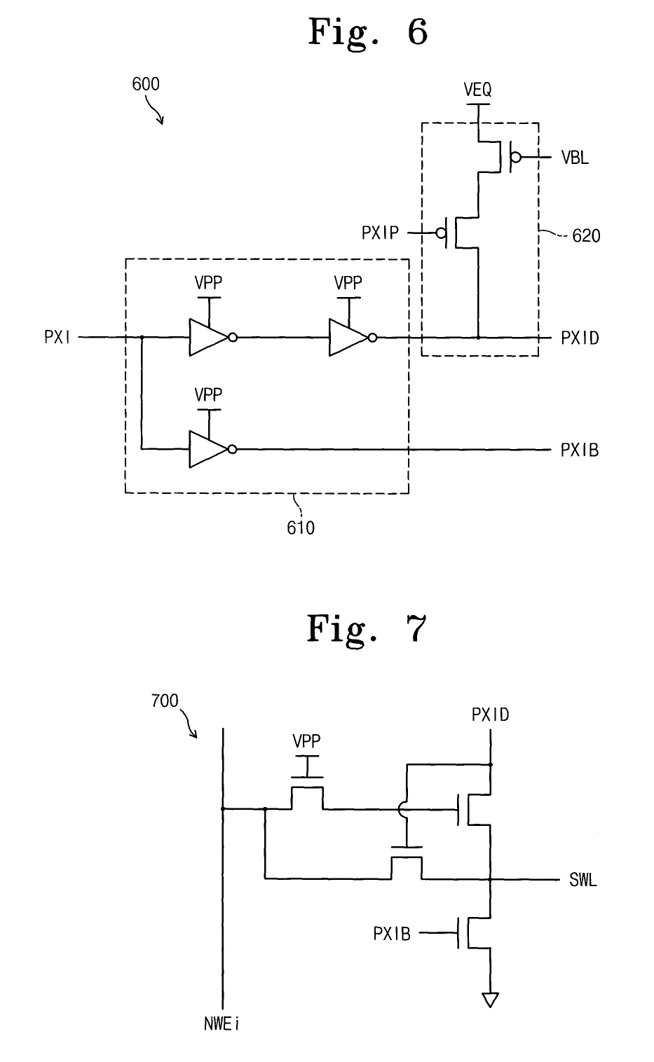

FIG. 6 shows the bitline equalizing voltage generator according to the second embodiment. The bitline equalizing voltage generator 600 includes a word line drive signal generator 610 and an equalizing voltage generator 620. The word line drive signal generator 610 receives a row address signal PXI provided from a row decoder (not shown) and then generates a wordline drive signal PXID and a word line reset signal PXIB, which are driven by a boost voltage VPP.

The wordline drive signal PXID and the wordline reset signal PXIB are applied to the sub-wordline driver 700 of FIG. 7 to activate a sub-wordline SWL with the boost voltage VPP. The sub-wordline driver 700, in response to a wordline enable signal NWEi sypplied from a main wordline driver (not shown)and the wordline drive signal PXID, activates the sub-wordline SWL with the boost voltage VPP and then enables the wordline of the memory cell coupled to the sub-wordline SWL. On the other hand, the sub-wordline driver 700 disables the wordline of the memory cell by resetting the sub-wordline SWL in response to the wordline reset signal PXIB.

In the FIG. 6, the bitline equalizing voltage driver 620, in response to the bitline pre-charge voltage VBL and a wordline drive pulse signal PIXP, drives the bitline equalizing voltage VEQ to the wordline drive signal PXID with the boost voltage VPP which is generated from the wordline drive signal generator 610. The wordline drive pulse signal PXIP is rendered of a pulse-type signal that is produced at the time when the row address PXI transitions from a high level to a low level.

Therefore, the bitline equalizing voltage driver 620 transfers the boost voltage VPP of the word line drive signal PXID to the bitline equalizing voltage VEQ during the low pulse duration of the wordline drive pulse signal PXIP. It means that the bitline equalizing voltage VEQ reuses the charges supplied from the boost voltage VPP that is the voltage level of the wordline drive signal PXID when the wordline drive signal PXID turns to a low level from a high level by the wordline drive signal generator 610 responding to a low level of the row address PXI.

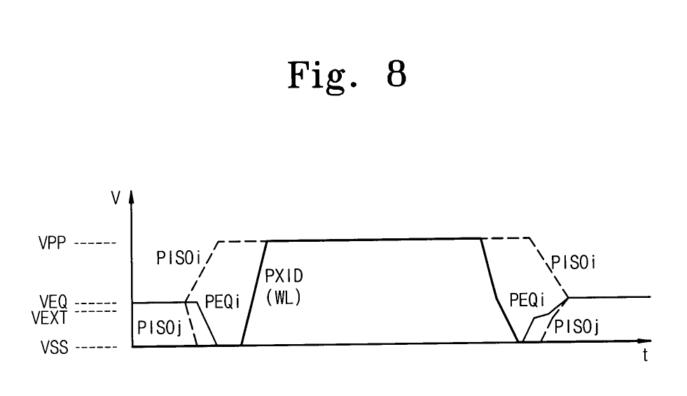

FIG. 8 shows voltage waveforms of the equalizing and isolation signals operating in the memory device using the bitline equalizing voltage generator as shown in FIG. 6. Referring to FIG. 8, when the first memory block 110 in the memory device 100 is selected, the first bitline equalizing signal PEQi is set to a low level, the first bitline isolation signal PISOi is set to a high level, the second bitline isolation signal PISOj is set to a low level, and a wordline drive signal PXID (in FIG. 8, it corresponds to the wordline WL because it is just a voltage level of the word line) of the first memory block 110 is set to the boost voltage VPP.

Afterwards, when the wordline WL is disabled, the boost voltage VPP on the word line WL is transferred to the first bitline equalizing signal PEQi, so that the first bitline equalizing signal PEQi rises up to the bitline equalizing voltage VEQ. Additionally, the first and second bitline isolation signals PISOi and PISOj become the bitline equalizing voltage VEQ, too.

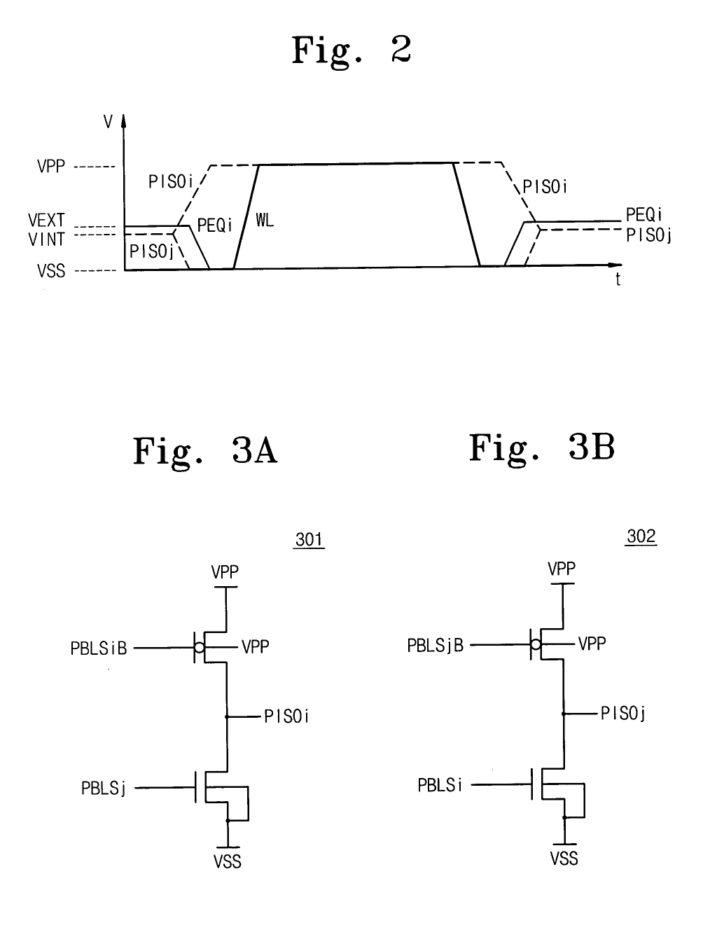

It means that, by recycling the charges supplied from the boost voltage VPP when the wordline WL is disabled for raising a voltage level of the first bitline equalizing signal PEQi, the activation level of the first bitline equalizing signal PEQi is set to the bitline equalizing voltage VEQ which level is higher than that of the external voltage VEXT of FIG. 2 according to the prior art.

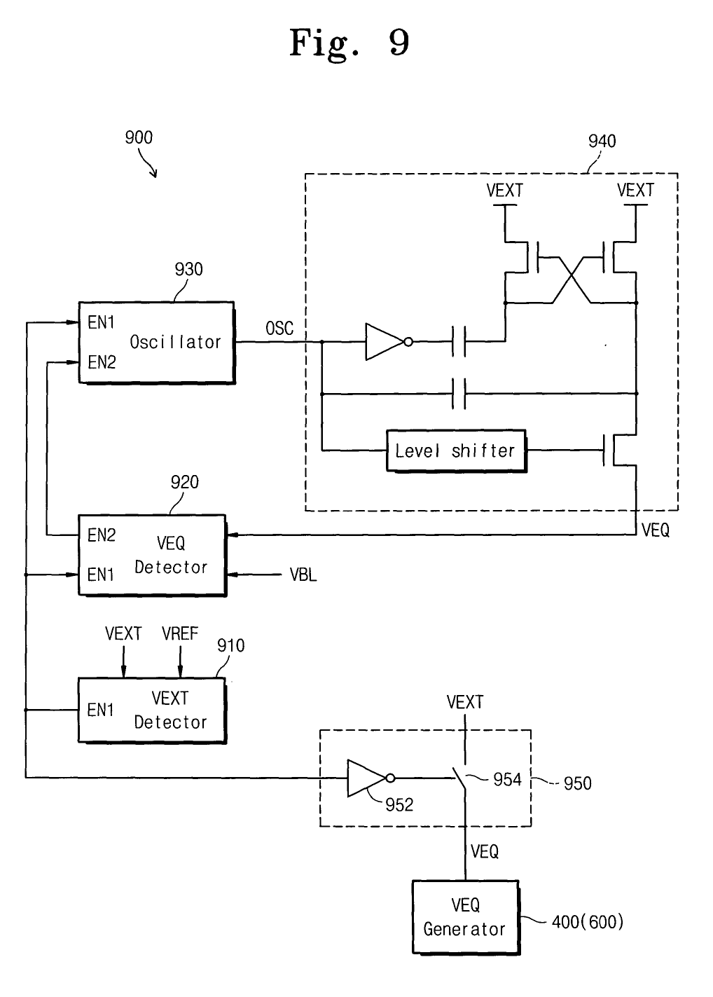

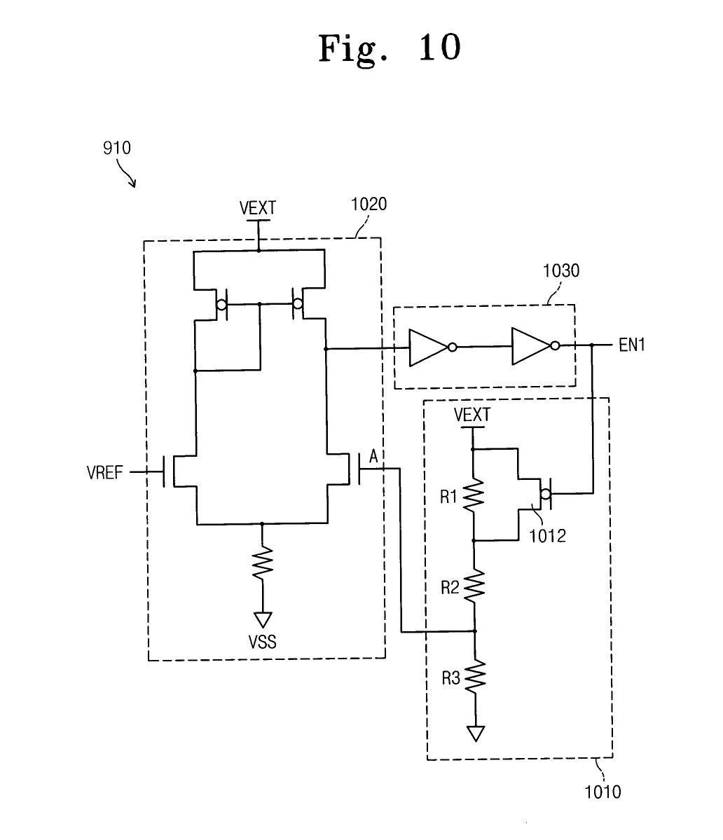

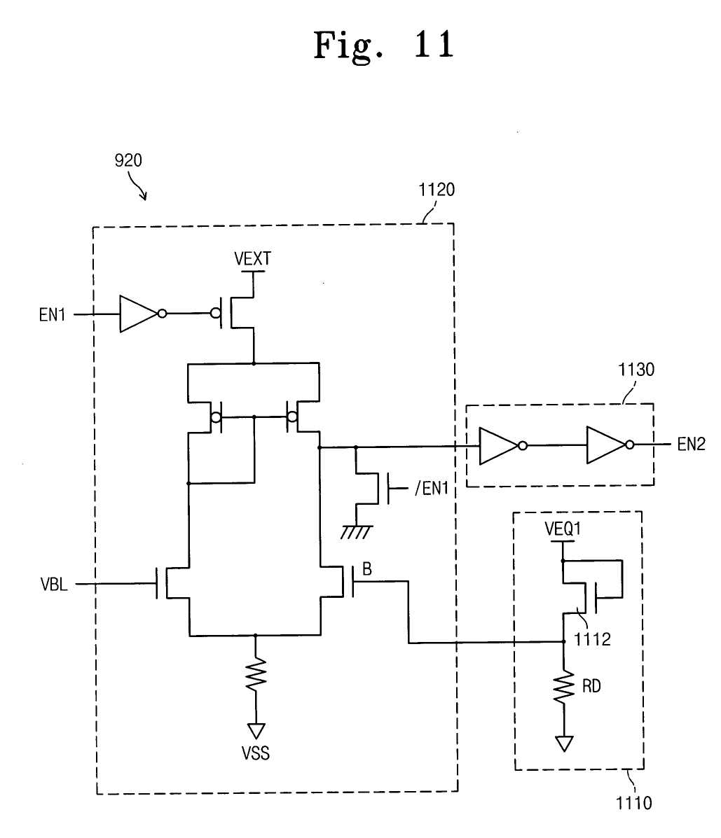

FIG. 9 shows a bitline equalizing voltage generator using the bitline equalizing voltage generators 400 and 600 of FIG. 4 or FIG. 6 and a charge pumping circuit 940. Referring to the FIG. 9, the bitline equalizing voltage generator 900 includes a first bitline equalizing voltage generator 400 (600), an external voltage detector 910, a bitline equalizing voltage detector 920, an oscillator 930, a charge pumping circuit 940, and a switch circuit 950. As above described, the first bitline equalizing voltage generator 400 (600) generates the bitline equalizing voltage VEQ by recycling (or reusing) the charges from the boost voltage VPP of the bitline isolation signal PISOi of FIG. 4 or those of the word line drive signal PXID of FIG. 6.

The external voltage detector 910 generates a first enable signal EN1 by comparing a reference voltage VREF with the external voltage VEXT. It is shown in FIG. 10 in detail.

Referring to FIG. 10, the external voltage detector 910 includes a voltage divider 1010, a comparator 1020, and a driver 1030. The voltage divider 1010 has a first resistor R1, a second resistor R2, and a third resistor R3 that are connected in series between the external voltage VEXT and the ground voltage VSS. A PMOS transistor 1012 is connected with the first transistor R1 in parallel and its gate receives the first enable signal EN1. The first resistor R1 has significant high resistance than those of the second and third resistors, wherein the second R2 and third transistor R3 has same resistance.

When the first enable signal EN1 is a low level, the output node A of the external voltage divider 1010 has half voltage of external voltage VEXT, i.e, VEXT/2. When the first enable signal EN1 is a high level, the output node A of the external voltage divider 1010 has a certain voltage lower than half voltage of external voltage VEXT. The comparator 1020 compares a reference voltage VREF with the voltage of the output node A on the voltage divider 1010 and then generates the first enable signal EN1 through the driver 1030. The reference voltage VREF is fixed to a half voltage of the external voltage VEXT.

The external voltage detector 910 operates as follows. When the external voltage VEXT comes to be low as compared with its normal voltage, the comparator 1020 generates the first enable signal of a high level by comparing a voltage level of the output node A, which is lower than VEXT/2 of the voltage divider 1010, with the reference voltage VREF having VEXT/2.

Afterwards, according to the rising of external voltage VEXT, when the output node A of voltage divider 1010 becomes above the level of VEXT/2, the output of the comparator 1020 generates the first enable signal EN1 of a low level. In response to the first enable signal EN1 of the low level, the PMOS transistor 1012 of the voltage divider 1010 is turned on. As a result of that, the level of the output node A comes to be higher than VEXT/2 and therefore the first enable signal EN1 holds a low level.

The bitline equalizing voltage detector 920 will be fully described in FIG. 11. Referring to FIG. 11, the bitline equalizing voltage detector 920 includes a bitline equalizing voltage down converter 1110, a comparator 1120, and a driver 1130. The bitline equalizing voltage down converter 1110 has a transistor RD and a diode connected NMOS transistor that are serially connected between bitline voltage VEQ and ground voltage VSS. Wherein the NMOS transistor 1112 has a high threshold voltage Vth. The output node B of the bitline equalizing voltage down converter 1110 produces a VEQ-Vth level that the bitline equalizing voltage VEQ drops as much as a threshold voltage of a NMOS transistor. When the fist enable signal EN1 is set to a high level, the comparator 1120 compares a bitline level VBL with the node B level. When the first enable signal EN1 is set to a low level, the comparator 1120 becomes to a low level. The output of the comparator 1120 generates a second enable signal EN2 though the driver 1130.

When the bitline equalizing voltage level VEQ comes to be low as compared with its normal voltage, the voltage level of output node B is lower than the bitline voltage VBL so that the output of the comparator 1120 becomes a high and therefore the second enable signal EN2 becomes a high level. Afterwards, according to the rising of bitline equalizing voltage VEQ, when it has a level as high as threshold voltage of NMOS transistor 1112 than bitline voltage level VBL, the level of the out node B reaches higher than that of the VBL. As a result of that, the output of the comparator 1129 becomes a low level and therefore the second enable signal EN2 generates a low level.

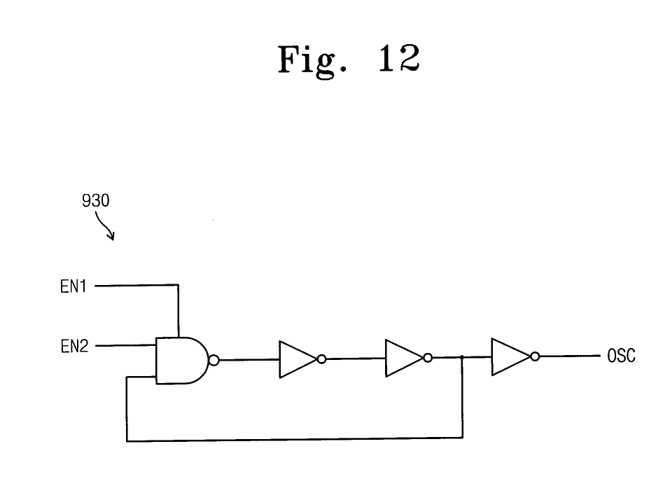

Referring to FIG. 12, the oscillator 930 generates an oscillation signal OSC in response to the first and second enable signals, EN1 and EN2. As shown in FIG. 9, the charge pumping circuit 940 in the bitline equalizing voltage generator 900 generates the bitline equalizing voltage VEQ by pumping the external voltage VEXT in response to the oscillation signal OSC.

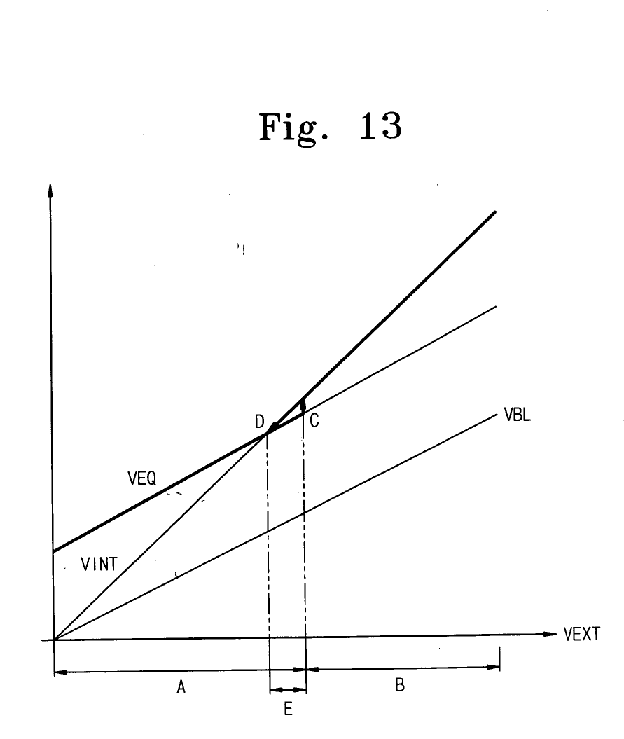

Such an operation of the bitline equalizing voltage generator 900 will be explained in accordance with the FIG. 13.

When the external voltage VEXT comes to be low as compared with its normal voltage, the first enable signal EN1 at the external voltage detector 910 is set to a high level so that a switch 954 is turned off because the output of inverter 952 is set to a low level. As a result of that, the external voltage VEXT is disconnected with bitline equalizing voltage VEQ. Wherein the bitline equalizing voltage VEQ is provided from the bitline equalizing voltage generator 400 (600).

After comparing the bitline equalizing voltage VEQ with the bitline pre-charge voltage VBL, when the bitline equalizing voltage VEQ is lower than VBL, the second enable signal EN2 that is output of the bitline equalizing voltage detector 920 is set to a high level. Accordingly, in response to the first and second enable signals, EN1 and EN2, each having a high level, the oscillator 930 is enabled and generates the oscillation signal OSC. According to the oscillation signal OSC, the bitline equalizing voltage VEQ rises by charge pumping operation of the charge pump circuit 940.

Referring to FIG. 13, the bitline equalizing voltage VEQ is higher than the bitline pre-charge voltage VBL by the threshold voltage Vth of the transistor 113 or 114 of FIG. 1. Afterwards, according to the increasing of the external voltage VEXT, if the external voltage is higher than the reference voltage VREF, the first enable signal EN1 as an output of the external voltage detector 910 is set to a low level and a switch 954 is turned on so that the bitline equalizing voltage VEQ is coupled to the external voltage VEXT.

At C point of FIG. 13, the bitline equalizing voltage VEQ comes to be the external voltage VEXT during the B period. The internal voltage VINT increases in accordance with the external voltage VEXT.

When the external voltage VXT decreases again, the bitline equalizing voltage VEQ downs along with the external voltage VEXT. But, at D point, the bitline equalizing voltage VEQ is higher than the bitline pre-charge voltage VBL by the threshold voltage Vth of the transistors 113 or 114

In that time, the first enable signal EN1 as an output of the external voltage detector 910 is set to a high level and the switch 954 is turned off, so that the bitline equalizing voltage detector 920 is enabled. The bitline equalizing voltage VEQ has a hysteresis characteristic during E period for generating the bitline equalizing voltage VEQ reliably which is adaptable to the fluctuation of the external voltage VEXT.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a first memory block and a second memory block, each memory block including a bitline pair;
a sense amplifier provided between the first memory block and the second memory block;
bitline isolation circuits for selectively connecting the first memory block and the second memory block to the sense amplifier in response to a first bitline isolation signal and a second bitline isolation signal;
bitline equalizing circuits for providing bitline precharge voltage to the bitline pair in response to a first bitline equalizing signal and a second bitline equalizing signal; and
a bitline equalizing voltage generator for generating bitline equalizing voltage by utilizing a voltage of the bitline isolation signals.

2. A semiconductor memory device according to the claim 1, wherein the bitline equalizing voltage generator comprising:
a first controller driven by a boost voltage level and generating a first control signal in response to a first block selection signal and a second block selection signal;
a second controller driven by an external voltage level and generating a second control signal in response to the first control signal;
an equalizer for generating the first bitline isolation signal and the second bitline isolation signal in response to the first control signal;
a driver for driving the first bitline isolation signal and the second bitline isolation signal in response to the second control signal; and
a transfer circuit for providing a half level of the equalized bitline isolation signal as bitline equalizing voltage when the first bitline isolation signal and the second bitline isolation signal are deactivated.

3. A semiconductor memory device according to the claim 1, wherein the memory device further comprising:
a bitline equalizing signal generator and a second bitline equalizing generator for selectively generating the first bitline equalizing signal and the second bitline equalizing signal fed from the bitline equalizing voltage or the external voltage in response to a first memory block selection signal and a second memory block selection signal.

4. A semiconductor memory device according to the claim 3, wherein the bitline equalizing signal generator comprising:
a first driver for providing the first bitline equalizing signal and the second bitline equalizing signal with the bitline equalizing voltage level in response to the first memory block selection signal and the second memory block selection signal; and
a second driver for providing the first bitline equalizing signal and the second bitline equalizing signal with the external voltage level in response to the first complement memory block selection signal.

5. A semiconductor memory device having a plurality of memory blocks comprising:
a sense amplifier provided between a first memory block and a second memory block;
bitline isolation circuits for selectively connecting the first memory block and the second memory block to the sense amplifier in response to a first isolation signal and a second bitline isolation signal;
bitline equalizing circuits for providing bitline precharge voltage to the bitline pair in response to a first bitline equalizing signal and a second bitline equalizing signal; and
a bitline equalizing voltage generator for connecting bitline equalizing voltage by utilizing a voltage of a word line drive signal.

6. a semiconductor memory device according to the claim 5, wherein the bitline equalizing voltage generator comprising:
a word line drive signal generator for generating the word line drive signal having a boost voltage level in response to a word line drive signal provided by a row decoder; and
a bitline equalizing voltage driver for serving the word line drive signal as the bitline equalizing voltage in response to a word line drive pulse signal which is generated in response to the bitline precharge and the word line address signal.

7. A semiconductor memory device according to the claim 6, wherein the bitline equalizing voltage driver comprising:
a first pmos transistor, a gate thereof being supplied the word line drive pulse signal, a source thereof being supplied the word line drive signal; and
a second pmos transistor, a gate thereof being supplied the bitline precharge voltage, a drain thereof being supplied the bitline equalizing voltage, a source thereof being connected to the drain of the first pmos transistor.

8. A semiconductor memory device having a plurality of memory blocks:
a bitline equalizing voltage generator generating a bitline equalizing voltage coupled to a bitline equalizing signal by recycling boost voltage of the bitline isolation signal;
an external voltage detector generating a first enable signal by comparing an external voltage with a reference voltage;
a bitline equalizing voltage detector generating a second enable signal by comparing the bitline equalizing voltage with a bitline precharge voltage;
an oscillator generating an oscillation signal in response to the first enable signal and the second enable signal;
a charge pumping circuit pumping the external voltage into the bitline equalizing voltage; and
a switching circuit coupling the external voltage with the bitline equalizing voltage in response to the first enable signal.

9. A semiconductor memory device according to the claim 8, wherein the external voltage detector comprising:
a voltage divider having a first to a third resistors which are serially connected between external voltage and ground voltage, wherein the first resistor is connected to a transistor at its both ends and a gate of the transistor receives a first enable signal;
a comparator comparing a reference voltage with a node voltage between the second and the third resistor of the voltage divider; and
a driver receiving the output of the comparator and generating the first enable signal.

10. A semiconductor memory device according to the claim 8, wherein the bitline equalizing voltage detector comprising:
a voltage down converter having a diode connected nmos transistor and a resistor which are serially connected between the bitline equalizing voltage and a ground voltage;
a comparator comparing the bitline precharge voltage with a node voltage between the NMOS transistor and the resistor; and
a driver receiving the output of the comparator and generating the second enable signal.
